(19) United States
(12) Patent Application Publication
(10) Pub. No.: US 2005/0039890 A1
(43) Pub. Date: Feb. 24, 2005

(54) Heat dissipating device and method of making it

(76) Inventors: Hsieh Kun Lee, Tu-Chen (TW); Chun-Chi Chen, Tu-Chen (TW); Wow Wu, Shenzhen (CN)

Correspondence Address: WEI TE CHUNG;FOXCONN INTERNATIONAL, INC., 1650 MEMOREX DRIVE, SANTA CLARA, CA, 95050, US

(21) Appl. No.: 10/900,717

(22) Filed: Jul. 27, 2004

(30) Foreign Application Priority Data
Aug. 8, 2003 (TW) 92004839

(51) Int. Cl. H05K 7/20

(52) U.S. Cl. 165/104.33; 165/182

(57) ABSTRACT

A method of combining fins (30) with heat pipe (20) includes the following steps: have a hole (34) defined on each fin, a turnup flange (36) is drawn from the hole, and a slit (38) is lengthways defined on the turnup flange; mounts the fins on the heat pipe with the turnup flanges enclosing the heat pipe; fills solder into the slit of each fin; put the fins and the heat pipe under high temperature to heat up; and takes the fins and the heat pipe out.

### BACKGROUND OF THE INVENTION

1. Field of the Invention

The present invention relates to a heat dissipating device and a method of making it, and particularly to a heat dissipating device incorporating a heat pipe and fins and a method of combining the fins with the heat pipe.

2. Prior Art

Electronic devices such as central processing units (CPUs) generate a lot of heat during normal operation. This can deteriorate their operational stability and damage associated electronic devices. Thus the heat must be removed quickly to ensure normal operation.

For cooling a CPU, one of the ways employed in the past has been to attach a heat sink to a top surface of the CPU. As the thermal load of the CPU increases, heat pipe was developed. Nowadays, fins are combined to a heat pipe to provide more efficient heat dissipation means.

Referring to FIG. 4, to mount fins 160 along the exterior surface of a heat pipe 140, a mandrel is pulled through the heat pipe 140, or hydraulic pressure is applied to the inside of the heat pipe 140. Thereby the heat pipe 140 is expanded and the fins 160 are held in place. However, air gap inevitablely exists between the heat pipe 140 and the fins 160 with such interferentially joint. This reduces heat transmit efficiency from the heat pipe 140 to the fins 160. To overcome the problem, stannum is filled between the fins and the heat pipe.

One way is to have the fins combined together firstly. A long tunnel is formed in the fins assembly for receiving a heat pipe. After stannum is spread on the tunnel, the heat pipe is inserted therein. However, it is difficult to have the stannum spread evenly in the long tunnel, and the stannum become more uneven after the heat pipe inserts therein.

The other way is to fill stannum as soon as each separate piece of fin is mounted on the heat pipe. The fins are mounted on the heat pipe piece by piece and the stannum is filled once by once. It is inefficient and tiresome.

### SUMMARY OF THE INVENTION

Accordingly, an object of the present invention is to provide a method of combining fins with a heat pipe which produce superior thermal interface between the fins and the heat pipe.

Another object of the present invention is to provide an efficient method of combining fins with heat pipe.

To achieve the above-mentioned objects, a method of combining fins with heat pipe in accordance with the present invention comprises the following steps: have a hole defined on each fin, a turnup flange is drawn from the hole, and a slit is lengthways defined on the turnup flange; mounts the fins on the heat pipe with the turnup flanges enclosing the heat pipe; fills solder into the slit of each fin; put the fins and the heat pipe under high temperature to heat up; and takes the fins and the heat pipe out.

Other objects, advantages and novel features of the present invention will be drawn from the following detailed description of a preferred embodiment of the present invention with attached drawings, in which:

### BRIEF DESCRIPTION OF THE DRAWINGS

FIG. 1 is an assembled view of a heat dissipating device in accordance with a preferred embodiment of the present invention;

FIG. 2 is an enlarged view of part II in FIG. 1;

FIG. 3 is a front view of a fin; and

FIG. 4 shows a portion of a heat dissipating device in accordance with a second embodiment of the present invention; and

FIG. 5 is a front view of a fin of the heat dissipating device in accordance with the alternative embodiment; and

FIG. 6 shows a portion of a heat dissipating device in accordance with a third embodiment of the present invention; and

FIG. 7 is an isometric view of a conventional combination of fins and a heat pipe.

### DETAILED DESCRIPTION OF THE INVENTION

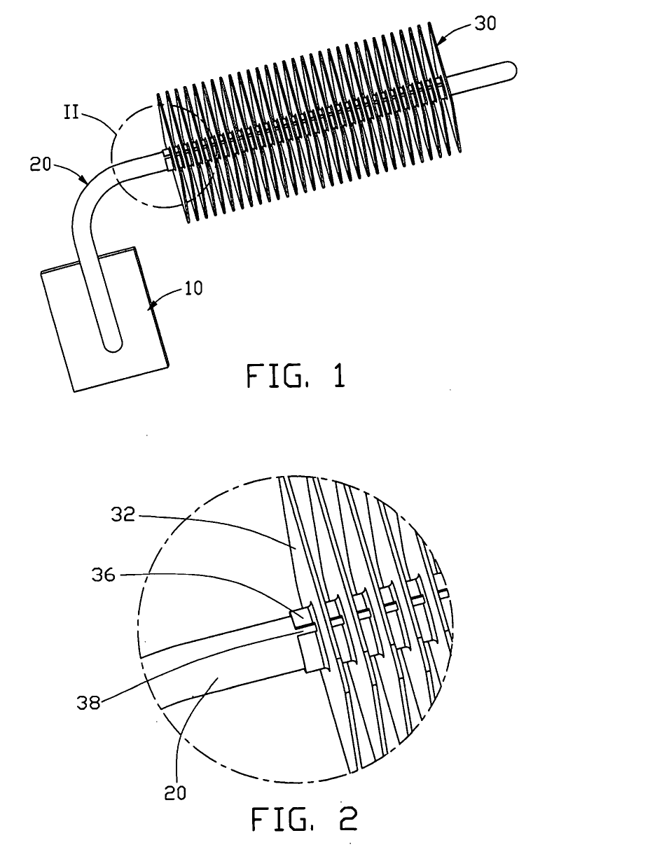

Referring to FIG. 1, a heat dissipating device in accordance with the preferred embodiment of the present invention comprises a base 10, a heat pipe 20 and a plurality of fins 30.

The base 10 is put on an electronic component (not shown), such as, a Central Processing Unit (CPU). One end of the heat pipe 20 touches the base 10 for absorbing heat. The other end of the heat pipe 20 is mounted with the fins 30 for dissipating heat.

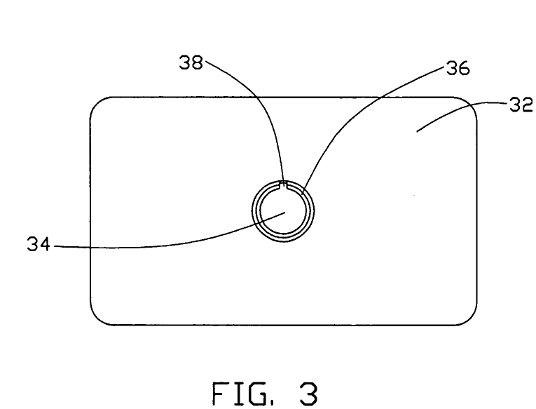

Referring to FIGS. 2 and 3, each fin 30 has a rectangular thin plate 32. A round hole 34 is defined at the center of the plate 32. A turnup flange 36 is drawn from the hole 34. A curved portion (not labeled) is formed between the plate 32 and the flange 36. A slit 38 is defined in the flange 36 and the curved portion. The slit 38 extends through the turnup flange 36 and one part of the curved portion in an axial direction of the hole 34.

In assembly, the fins 30 are mounted on the heat pipe 20 one by one. Alternatively, the fins 30 can be combined together before the fins 30 are mounted to the heat pipe 20. The turnup flange 36 of each fin 30 abut against a foregoing fin, and enclose the heat pipe 20. The slits 38 on the fins 30 are preferably in a line.

After the fins 30 are mounted on the heat pipe 20, stannum (or other solder) is filled in each slit 38 by welding torch (not shown). Then the combination of the fins 30 and the heat pipe 20 are put into an oven (not shown) for heating up. The stannum has a low melting point than the heat pipe 20 and the fins 30. Under high temperature, the stannum melts and flows into the gaps between the exterior surface of the heat pipe 20 and the interior surface of the turnup flanges 36 of the fins 30. The combination of the heat pipe 20 and the fins 30 is turned in the oven, so that the melting stannum can flow into the gap between the heat pipe 20 and the fins 30 fully. But the slits 38 should be kept facing up, lest the stannum overflow. The time that the combination stays in the oven depends on the oven temperature, the size of the combination and the volume of the stannum. Then the assembly is taken out of the oven and cooled down. Thereby, the fins 30 are securely mounted on the heat pipe 20 with superior thermal interface therebetween.

Finally, the combination of the heat pipe 20 and the fins 30 is attached to the base 10.

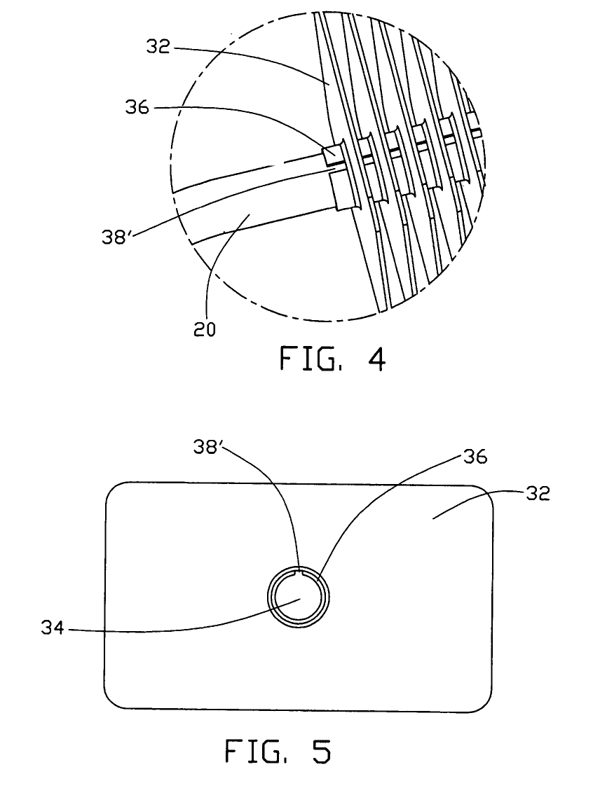

FIGS. 4-5 show a heat dissipating device in accordance with a second embodiment of the present invention. The heat dissipating device of the second embodiment is similar to the heat dissipating device of the first embodiment except that the slits 38′ thereof end at the respective junction of the flange 36 and the curved portion located between the flange 36 and the plate 32 in the axial direction of the hole 34.

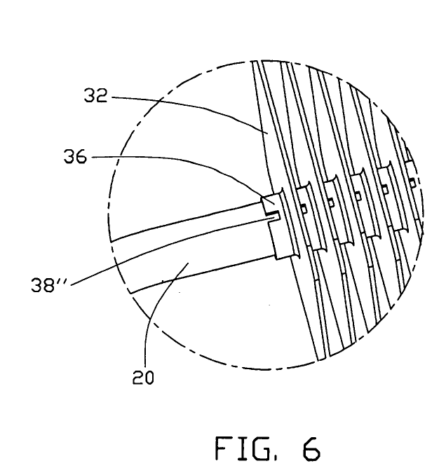

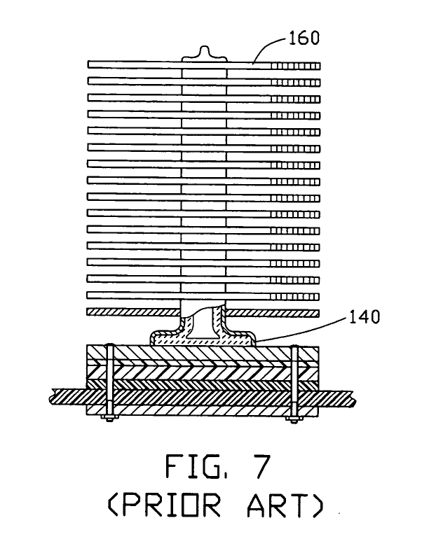

FIG. 6 shows a heat dissipating device in accordance with a third embodiment of the present invention. The heat dissipating device of the third embodiment is similar to the heat dissipating device of the first embodiment except that the slit 38″ thereof partly extend through the flange 36 and not extend into the curved portion located between the flange 36 and the plate 32 in the axial direction of the hole 34 of the fins.

It is understood that the invention may be embodied in other forms without departing from the spirit thereof. Thus, the present examples and embodiments are to be considered in all respects as illustrative and not restrictive, and the invention is not to be limited to the details given herein.

1. A method of combining fins with a heat pipe comprising the following steps: having a hole defined in each fin, a turnup flange being drawn from the hole,
a slit being defined in the turnup flange in an axial direction of the hole; mounting the fins on the heat pipe with the turnup flanges enclosing the heat pipe;
filling solder into the slit of each fin;
putting the fins and the heat pipe under a circumstance with high temperature to heat up; and
cooling the fins and the heat pipe.

2. The method as claimed in claim 1, wherein the hole is defined at the center of the fine.

3. The method as claimed in claim 1, wherein the slit extends through the turnup flange in an axial direction of the hole.

4. The method as claimed in claim 1, wherein the turnup flange of each fin abuts against an adjacent fin.

5. The method as claimed in claim 1, wherein the mounting step mounts the fins on the heat pipe with the slits in a line.

6. The method as claimed in claim 1, wherein the solder is stannum.

7. The method as claimed in claim 1 further comprising a step of turning the fins and the heat pipe under the circumstance with high temperature.

8. The method as claimed in claim 7, wherein the slits of the fins are kept facing up while the fins and the heat pipe is turned under the circumstance with high temperature.

9. A heat dissipating device comprising:
a heat pipe;
a plurality of fins stacked along the heat pipe in the axial direction of the heat pipe, each fin comprising a plate defining a hole for extending of the heat pipe therethrough and a flange extending from the plate along the periphery of the hole, a slit being defined in the flange without extending through the plate in the axial direction of the heat pipe; and
solder filled in the slits for combining the fins to the heat pipe.

10. The heat dissipating device as claimed in claim 9, wherein each fin further comprises a curved portion connected between the plate and the flange.

11. The heat dissipating device as claimed in claim 10, wherein the slit extends through the flange and into the curved portion in the axial direction of the heat pipe.

12. The heat dissipating device as claimed in claim 10, wherein the slit extends through the flange and ends at the junction of the flange and the curved portion in the axial direction of the heat pipe.

13. The heat dissipating device as claimed in claim 10, wherein the slit partly extends through the flange in the axial direction of the heat pipe.

14. A heat dissipating device comprising:
a heat pipe;
a plurality of fins stacked along the heat pipe in the axial direction of the heat pipe, each fin comprising a plate defining a through hole for extension of the heat pipe therethrough and a flange extending from the plate along a periphery of the hole in said axial direction for a distance, a slit inwardly extending from an outer edge of said flange toward the corresponding plate while terminated before reaching the plate so as to keep the periphery of the hole complete for symmetrically and fully circumferentially holding the heat pipe therein; and
solder filled in the slits for combining the fins to the heat pipe.

15. The heat dissipating device as claimed in claim 14, wherein said slit extends along said axial direction.
